(19) United States
(12) Patent Application Publication
(10) Pub. No.: US 2012/0315709 A1
(43) Pub. Date: Dec. 13, 2012

(54) PROCESS AND APPARATUS FOR PRODUCING A SUBSTRATE

(75) Inventors: Tommi Vainio, Vantaa (FI); Jarmo Skarp, Espoo (FI)

(73) Assignee: BENEQ OY, Vantaa (FI)

(21) Appl. No.: 13/511,905

(22) PCT Filed: Dec. 13, 2010
(86) PCT No.: PCT/FI2010/051016

§ 371 Date: Aug. 17, 2012

(30) Foreign Application Priority Data
Dec. 15, 2009 (FI) 20090476

(51) Int. Cl. H01L 31/18; B05B 1/24

(52) U.S. Cl. 438/5; 118/302; 257/E31.11

(57) ABSTRACT

Process for producing a solar cell substrate, where metal particles are deposited on the surface of substrate. Metal particles are produced by liquid flame spraying method in such a way that the mean diameter of the particles to be between 30 nm and 150 nm and the deposition process is controlled in such a way that the average distance between particles is not more than four times the mean diameter of particles. Apparatus for carrying out such process.

### TECHNICAL FIELD

The present invention relates to a solar cell substrate useful in the production of efficient solar cells, especially in the production of sensitized solar cells. The solar cell substrate is manufactured from glass and includes metallic particles in or on the glass substrate. The metallic particles are preferably silver, gold or copper particles. The present invention also relates to an apparatus for manufacturing such solar cell substrates.

### BACKGROUND ART

Thin film solar cells play an important role in low cost photovoltaics, but at the cost of reduced efficiencies when compared to wafer based cells. However, the efficiency of thin film solar cells (also called photovoltaic (PV) cells) can be improved by using the optical properties of sub-wavelength metal nanoparticles. Sub-wavelength metal particles support surface modes called surface plasmons. A plasmon is a density wave of charge carriers. Localized surface plasmon resonances are associated with excellent improvements of field amplitudes in spatial regions near particles which generate plasmons. The enhancement of the local fields may result in improved optical properties. Thus the surface plasmons cause metal particles to strongly scatter light into the underlying substrate, enhancing the absorption of solar light into the solar cell. Suitable metals include gold, silver and copper.

Surface plasmons have been produced on the surface of the glass- and silicon-based solar cell substrates by using the slow evaporation method, thermal evaporation method and photocatalytic deposition. However, none of these production methods is capable of producing the surface plasmons with such a speed that the production could be integrated to the current thin film solar cell production lines, where the substrate moves at the speed of 1-20 m/min in the production line. Thus there exists a need for a process for producing solar cell substrates comprising sub-wavelength metal particles.

### DISCLOSURE OF INVENTION

The Finnish patent FI98832, Liekki Oy, Mar. 16, 1997, describes a method for producing noble metal particles, such as platinum, silver and gold particles by using a liquid flame spraying (LFS) process. In the LFS method a metal salt is dissolved into a suitable solvent, such as water or alcohol and the liquid is fed into a liquid flame spraying gun. In the gun the liquid is first atomized into fine droplets and the droplets are essentially immediately fed into a thermal reactor, typically into a flame. The liquid and the metal evaporates in the flame. The evaporated metal then forms nanoparticles via the well-known gas-particle route. The size of the particles depends e.g. on the mass feed rate and the mean particle size is typically between 10 and 200 nm.

An essential feature of the present invention is that by controlling the mass feed rate into the liquid flame spraying apparatus in comparison to the substrate feed rate we are able to deposit sub-wavelength metal particles on a substrate so that the mean particle diameter is from 30 nm to 150 nm, preferably from 80 nm to 120 nm and the average distance between the sub-wavelength particles on the substrate surface is equal to or less than 4 times the mean particle diameter. In the preferred embodiment this is achieved by quenching the particle flow generated in the liquid flame spraying apparatus by using gas flows which cool down and widen the particle flow.

### BRIEF DESCRIPTION OF DRAWINGS

In the following, the invention will be described in more detail with reference to the appended principle drawings, in which

FIG. 1 is a schematic view of a substrate produced by the present invention; and

FIG. 2 is a schematic view of invented process.

For the sake of clarity, the figures only show the details necessary for understanding the invention. The structures and details which are not necessary for understanding the invention and which are obvious for anyone skilled in the art have been omitted from the figures in order to emphasize the characteristics of the invention.

### MODES FOR CARRYING OUT THE INVENTION

For high-efficiency solar cells it is of top importance that a maximum fraction of the solar light absorbs on the cell layer where the photoelectric conversion takes place. The absorption can be improved by taking advantage of plasmon resonance generated by sub-wavelength metal particles. The plasmon resonance particles are preferably deposited on the substrate required for the thin-film solar cell production. It is advantageous to deposit such metal particles during e.g. the production of the transparent conductive oxide (TCO) layer production, as the solar cells requires at least one of such TCO layer for current flow. Typically such TCO layers are produced either by sputtering or by pyrolytic processes. In the pyrolytic process the TCO film is produced on a glass substrate with temperature 550-700° C. moving at 1-20 m/min.

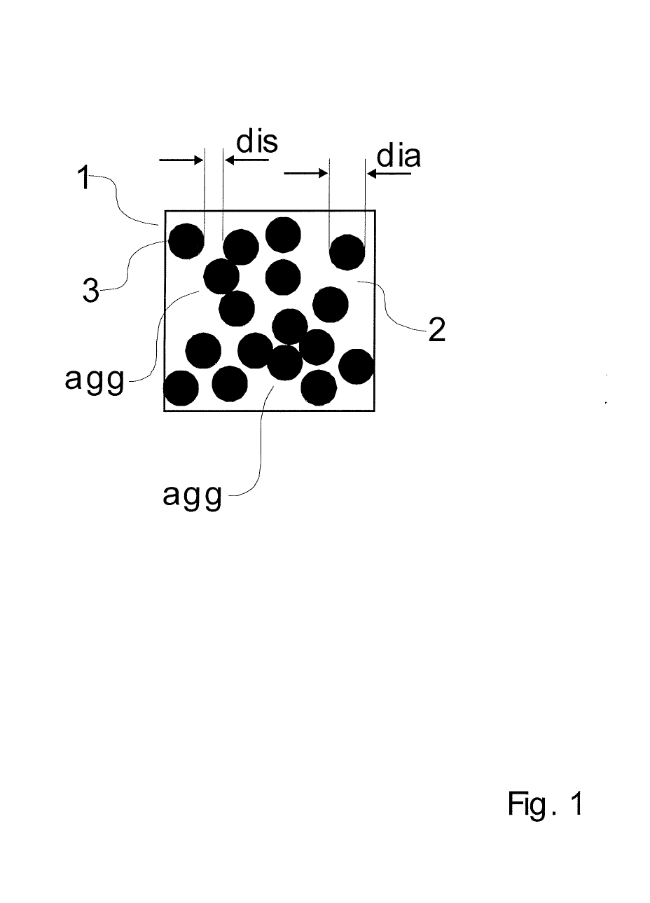

FIG. 1 shows a schematic picture of a substrate 1 produced by the present invention. The flat glass substrate 2 has a thickness of 2 mm-6 mm. Silver particles 3, with a mean diameter of approximately 100 nm are deposited on the glass substrate 2. The distance between the silver particles (marked with “dis”), is preferably less than four (4) times the mean diameter (i.e. 400 nm), and more preferably less than two and a half (2,5) times the mean diameter (i.e. 250 nm). With such a short average distance, the plasmon resonance frequency shifts towards higher wavelengths (red) and the solar radiation absorption of the solar cell is exceptionally increased. The silver particles may be aggregated (marked as “agg”), preferably as to chain-like aggregates. In the aggregates the individual metal particles are hold together by substantially weak forces, such as by the van der Wals force. In the best embodiment such aggregates are formed by quenching the particle flow of the liquid flame spraying process.

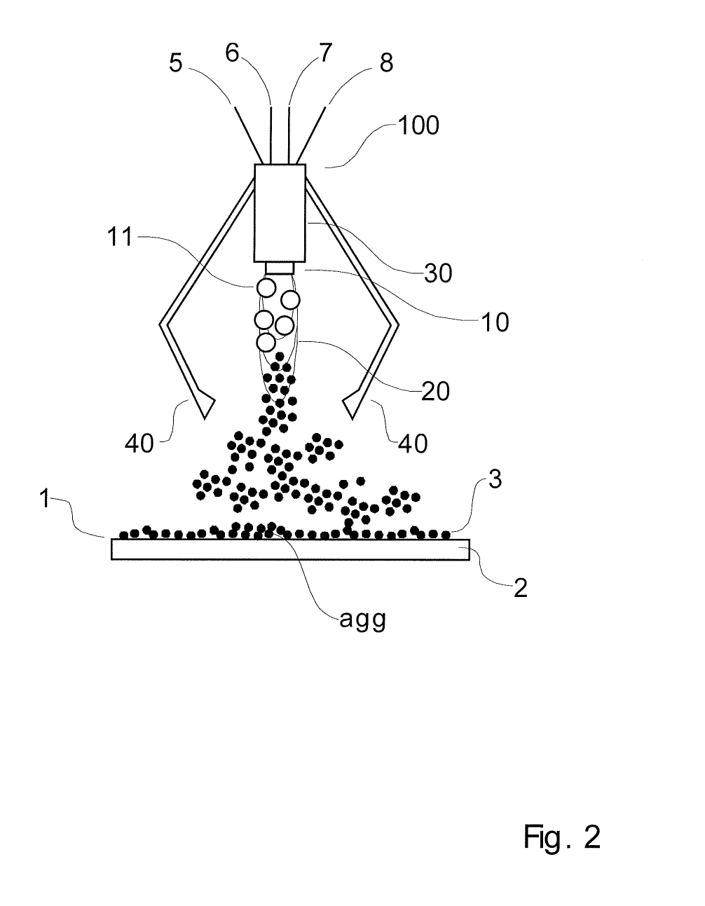

FIG. 2 shows a schematic picture of an embodiment of the process under the present invention. The liquid flame spraying apparatus 100 described in the Finnish patent FI98832 is used to produce the required silver particles 3. 44 g of silver nitrate (AgNO₃) is dissolved into 100 cm³ of water (H₂O). The flow rate of the solution is 15 cm³/min. Hydrogen (H₂) is supplied through conduit 7 at a flow rate of 100 dm³/min and oxygen (O₂) is supplied through conduit 8 at a flow rate of 50 dm³/min. The hydrogen flow is fed into the two-fluid atomizer 10, where the gas flow atomizes the liquid flow into droplets 11. The mean diameter of droplets 11 is preferably less than 10 micrometers. Droplets 11, including the silver metal which they contain, are essentially evaporated in flame 20 generated by igniting the hydrogen/oxygen mixture. At least part of the metal vapor nucleates and further metal condensates on the nuclei thus forming nanosize metal particles 3. Nitrogen (N₂) gas is fed into the liquid flame spraying apparatus 100 through conduit 5 at a flow rate of 200 dm³/min. Nitrogen is further directed to the gas nozzles 40, and the nitrogen gas escaping from the nozzles 40 effectively quenches the metal particle flow, thus stopping the further growth of particles 3. It is an essential feature of the present invention that the mass flow of the silver nitrate, position of the nozzles 40 and mass flow of nitrogen are controlled and by that way the mean diameter of particles 3 can be set to a value between 30 and 150 nm, preferably between 80 and 120 nm. Metal particles 3 are deposited on the substrate 2 forming a solar cell substrate 1. At least part of the particles 3 may be deposited as aggregates agg.

When glass is used as substrate 2, the temperature of substrate 2 is preferably between 530° C. and 700° C. At different temperatures the metal particles are deposited either on the substrate 2 or at least partly in the substrate 2. This has an effect on tuning the required plasmon resonance frequency.

In one embodiment where the glass substrate 2 is essentially 4 mm thick flat glass plate, the outer dimensions of the plate are 1400 mm×1100 mm, and the substrate 2 is moving on a glass coating line at a speed of 5 m/min, silver particles can be deposited on substrate 2, when the coating is carried out using three (3) liquid flame spraying apparatus of FIG. 2 traversing across the substrate 2 at a speed of 50 m/min, essentially perpendicularly against the direction of the glass coating line. Said traversing is preferably achieved by enabling the apparatus to repeatedly sweep over the width of the glass coating line back and forth. By adjusting the traversing speed of the liquid flame spraying apparatus, the average distance (dis) between particles (3) can be controlled.

By combining, in various ways, the modes disclosed in connection with different embodiments of the invention presented above, it is possible to produce various embodiments of the invention in accordance with the spirit of the invention. Therefore, the above-presented examples must not be interpreted as restrictive to the invention, but the embodiments of the invention can be freely varied within the scope of the inventive features presented in the claims.

1. Process for producing a solar cell substrate, where metal particles are deposited on the surface of substrate, comprising:
a. producing metal particles by a liquid flame spraying method;
b. adjusting the mass flow of the precursor for the metal particles production to tune the mean diameter of the particles between 30 nm and 150 nm;
c. directing the particle flow towards the substrate; and
d. controlling the liquid flame spraying apparatus traverse speed and the line speed carrying the substrate in such a way that the average distance between particles is not more than four times the mean diameter of particles.

2. Process of claim 1, comprising quenching the flow of the metal particles, generated by the liquid flame spraying method, by gas flow to tune the mean diameter of the particles.

3. (canceled)

4. Process of claim 1, comprising:
a. producing metal particles by a liquid flame spraying method;
b. adjusting the mass flow of the precursor for the metal particles production through an atomizer to less than 10 g/min to tune the mean diameter of the particles between 80 nm and 120 nm;
c. directing the particle flow towards the substrate; and
d. controlling the liquid flame spraying apparatus traverse speed and the line speed carrying the substrate in such a way that the traverse speed is roughly ten times the line speed.

5. The process of claim 1, wherein the metal particles comprise silver, gold or copper.

6. The process of claim 1, wherein the metal particles are at least partly agglomerated.

7. The process of claim 1, wherein substrate is essentially glass and metal particles are at least partly deposited in the glass substrate.

8. The process of claim 7, wherein the temperature of substrate is between 530° C. and 700° C. during particle deposition.

9. (canceled)

10. Apparatus for the production of solar cell substrate, comprising
a. liquid frame spraying apparatus;
b. means for supplying liquid raw materials into flame;
c. means for forming flame; and
d. gas supply nozzles for supplying quenching gas essentially towards the metal particles generated in flame.
